(19) United States
(12) Patent Application Publication
(10) Pub. No.: US 2024/0421148 A1
(43) Pub. Date: Dec. 19, 2024

(54) SEMICONDUCTOR INTEGRATED CIRCUIT DEVICE

(71) Applicant: Socionext Inc., Kanagawa (JP)

(72) Inventor: Isaya SOBUE, Yokohama-shi (JP)

(21) Appl. No.: 18/819,621

(22) Filed: Aug. 29, 2024

Related U.S. Application Data
(63) Continuation of application No. PCT/JP2023/006559, filed on Feb. 22, 2023.

(30) Foreign Application Priority Data
Mar. 2, 2022 (JP) 2022-031872

(51) Int. Cl. H01L 27/02; H01L 29/06; H01L 29/423; H01L 29/775; H01L 29/786

(52) U.S. Cl. CPC H01L 27/0255; H01L 29/0673; H01L 29/42392; H01L 29/775; H01L 29/78696

(57) ABSTRACT

In an ESD protection circuit using a nanosheet device, a first device structure constituting one of the anode and the cathode is opposed to a second device structure constituting the other in the Y direction, and to a third device structure constituting the other in the X direction. The first device structure includes a pad group of a first conductivity type, and the second and third device structures each include a pad group of a second conductivity type. The length of a range in the X direction in which the pad group of the first device structure is opposed to the pad group of the second device structure in the Y direction is greater than the length of a range in the Y direction in which it is opposed to the pad group of the third device structure in the X direction.

### CROSS-REFERENCE TO RELATED APPLICATIONS

This is a continuation of International Application No. PCT/JP2023/006559 filed on Feb. 22, 2023, which claims priority to Japanese Patent Application No. 2022-031872 filed on Mar. 2, 2022. The entire disclosures of these applications are incorporated by reference herein.

### BACKGROUND

The present disclosure relates to a semiconductor integrated circuit device using a nanosheet device, and more particularly to a layout configuration for an electrostatic discharge (ESD) protection circuit for protecting a circuit from damage caused by ESD.

As shown in FIG. 14, ESD protection circuits 251 and 252 are generally provided between a signal terminal (input/output terminal) 253 and a power terminal 254 or between the signal terminal 253 and a ground terminal 255. As the ESD protection circuit, various protection elements are used depending on the use. Among them, a diode is often used as the protection element because of its good discharge property.

Japanese Unexamined Patent Publication No. 2019/043888 discloses a configuration of an ESD protection circuit using a nanowire field effect transistor (FET). In this configuration, pads provided on both ends of a nanowire of a nanowire FET are used for a diode. Specifically, a diode is formed between pads of different conductivity types opposed to each other.

In a nanowire FET, pads provided on both ends of a nanowire are generally formed by epitaxial growth from the nanowire. It is therefore very difficult to form only pads.

In the configuration of the ESD protection circuit disclosed in the cited patent document, out of regions of different conductivity types, i.e., the p-conductivity type and the n-conductivity type, opposed to each other, nanowire portions do not function as the diode. The reason is that, while a diode serves to pass a current through a substrate, the nanowire is not in contact with the substrate. Therefore, the configuration of the cited patent document increases the area for forming a diode.

On the other hand, in recent years, a device using a nanosheet, obtained by enlarging the size of the nanowire in the gate width direction into a sheet-like shape, has been studied and developed. However, no examination on effective structures of an ESD protection circuit using a nanosheet device has not been performed.

An objective of the present disclosure is providing an effective structure of an ESD protection circuit using a nanosheet device.

### SUMMARY

According to one mode of the present disclosure, a semiconductor integrated circuit device including a nanosheet field effect transistor (FET) includes an electrostatic discharge (ESD) protection circuit, wherein the nanosheet FET includes a nanosheet and pads connected to both ends of the nanosheet, the ESD protection circuit includes a first device structure constituting one of an anode and a cathode of a diode, a second device structure constituting the other of the anode and the cathode of the diode, opposed to the first device structure in a first direction, and a third device structure constituting the other of the anode and the cathode of the diode, opposed to the first device structure in a second direction perpendicular to the first direction, the first device structure includes one, or two or more first gate interconnects arranged in the second direction, extending in the first direction, and a first pad group constituted by pads of a first conductivity type extending in the first direction, placed on both sides of the first gate interconnect in the second direction, the second device structure includes one, or two or more second gate interconnects arranged in the second direction, extending in the first direction, and a second pad group constituted by pads of a second conductivity type extending in the first direction, placed on both sides of the second gate interconnect in the second direction, the third device structure includes one, or two or more third gate interconnects arranged in the second direction, extending in the first direction, and a third pad group constituted by pads of the second conductivity type extending in the first direction, placed on both sides of the third gate interconnect in the second direction, and the length of a range in the first direction in which the first pad group and the third pad group are opposed to each other in the second direction is greater than the length of a range in the second direction in which the first pad group and the second pad group are opposed to each other in the first direction.

According to the above mode, the first device structure constituting one of the anode and the cathode is opposed to the second device structure constituting the other of the anode and the cathode in the first direction, and opposed to the third device structure constituting the other of the anode and the cathode in the second direction. The first device structure includes a first pad group constituted by pads of a first conductivity type extending in the first direction, placed on both sides of a first gate interconnect in the second direction. The second device structure includes a second pad group constituted by pads of a second conductivity type extending in the first direction, placed on both sides of a second gate interconnect in the second direction. The third device structure includes a third pad group constituted by pads of the second conductivity type extending in the first direction, placed on both sides of a third gate interconnect in the second direction. The length of a range in the first direction in which the first pad group and the third pad group are opposed to each other in the second direction is greater than the length of a range in the second direction in which the first pad group and the second pad group are opposed to each other in the first direction. With this, since a diode large in capability using a nanosheet device can be configured, a small-area ESD protection circuit can be formed.

According to the present disclosure, an effective structure of an ESD protection circuit using a nanosheet device can be implemented.

### BRIEF DESCRIPTION OF THE DRAWINGS

FIG. 1 is a plan view schematically showing the entire structure of a semiconductor integrated circuit device according to an embodiment.

FIG. 2 is a simplified configuration diagram of a signal IO cell in FIG. 1.

FIGS. 3A and 3B are views showing part of a configuration of an ESD portion for VDDIO in the embodiment, in which FIG. 3A is a plan view and FIG. 3B is a cross-sectional view.

FIGS. 4A and 4B are views showing part of a configuration of an ESD portion for VSS in the embodiment, in which FIG. 4A is a plan view and FIG. 4B is a cross-sectional view.

FIG. 5 is a plan view showing a configuration of an ESD portion for VDDIO in Alteration 1.

FIG. 6 is a plan view showing a configuration of an ESD portion for VDDIO in Alteration 2.

FIG. 7 is a plan view showing a configuration of an ESD portion for VDDIO in Alteration 3.

FIG. 8 is a plan view showing a configuration of an ESD portion for VDDIO in Alteration 4.

FIG. 9 is a plan view showing a configuration of an ESD portion for VDDIO in Alteration 5.

FIG. 10 shows a configuration example of interconnects placed above the configuration of FIG. 9.

FIG. 11 is a plan view showing a configuration of an ESD portion for VDDIO in Alteration 6.

FIG. 12 is a plan view showing a configuration of an ESD portion for VDDIO in Alteration 7.

FIG. 13 is a schematic view showing a basic structure of a nanosheet FET.

FIG. 14 is a circuit diagram showing the relationship between a signal terminal and ESD protection circuits.

### DETAILED DESCRIPTION

An embodiment of the present disclosure will be described hereafter with reference the accompanying drawings.

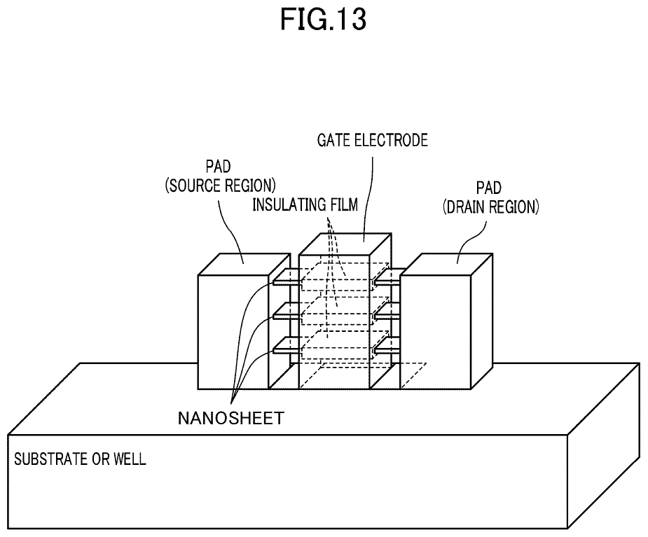

FIG. 13 is a schematic view showing a basic structure example of a nanosheet FET. The nanosheet FET is a FET using a thin sheet-like structure (nanosheet) through which a current flows. The nanosheet is formed of silicon, for example. As shown in FIG. 13, such nanosheets are formed above a substrate to extend in the horizontal direction in parallel with the substrate, and their both ends are connected to structures that are to be the source region and drain region of the nanosheet FET. As used herein, in the nanosheet FET, such structures serving as the source region and drain region of the nanosheet FET, connected to both ends of the nanosheets, are called pads. The pads are formed by epitaxial growth from the nanosheets, for example.

Each of the nanosheets is surrounded by a gate electrode via an insulating film such as a silicon oxide film. The pads and the gate electrode are formed on the substrate. With this structure, the channel region of the nanosheet, surrounded by the gate electrode entirely on the top, both sides, and the bottom, is subjected to a uniform electric field, whereby the FET exhibits good switching characteristics.

Note that while portions of the pads at least connected to the nanosheets serve as the source/drain regions, portions located under the portions connected to the nanosheets do not necessarily serve as the source/drain regions in some cases. Note also that part of the nanosheets (portions that are not surrounded by the gate electrode) may serve as the source/drain regions in some cases.

In FIG. 13, three nanosheets are arranged in the vertical direction, i.e., in the direction perpendicular to the substrate. The number of nanosheets arranged in the vertical direction is not limited to three, but one nanosheet may be placed, or two, or four or more nanosheets may be arranged in the vertical direction.

### First Embodiment

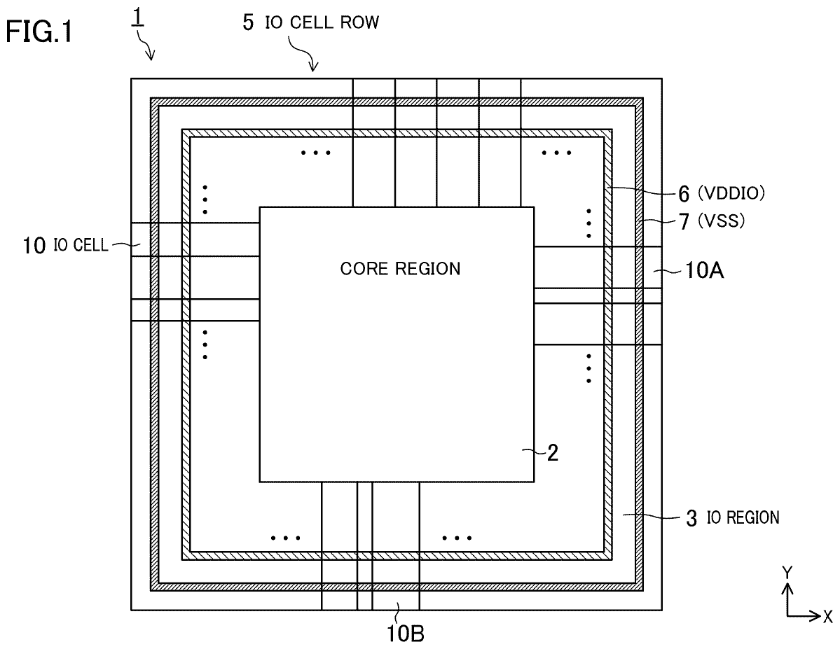

FIG. 1 is a plan view schematically showing the entire configuration of a semiconductor integrated circuit device (semiconductor chip) according to the embodiment. In FIG. 1, the horizontal direction in the figure is indicated as the X direction, and the vertical direction in the figure is indicated as the Y direction (this also applies to the figures to follow). A semiconductor integrated circuit device 1 shown in FIG. 1 includes: a core region 2 in which inner core circuits are formed; and an IO region 3 provided around the core region 2, in which interface circuits (IO circuits) are formed. In the IO region 3, an IO cell row 5 is formed to surround the core region 2 in a peripheral portion of the semiconductor integrated circuit device 1. Although illustration is simplified in FIG. 1, a plurality of IO cells 10 constituting the interface circuits are arranged in the IO cell row 5. The semiconductor integrated circuit device 1 is assumed to have nanosheet FETs in the core region 2 and the IO region 3.

The IO cells 10 include signal IO cells for input, output, or input/output of signals, power IO cells for supply of a ground potential (power supply voltage VSS), and power IO cells for supply of power (power supply voltage VDDIO) mainly to the IO region 3. VDDIO is 1.8 V, for example. In FIG. 1, an IO cell 10A for signal input/output is placed on the right side of the core region 2 in the figure, and an IO cell 10B for signal input/output is placed on the lower side of the core region 2 in the figure.

Power lines 6 and 7 extending in the direction in which the IO cells are arranged are provided in the IO region 3. The power lines 6 and 7 are each formed in a ring in the peripheral portion of the semiconductor integrated circuit device 1 (these power lines are also called the ring power lines). The power line 6 supplies VDDIO and the power line 7 supplies VSS. Note that, although each of the power lines 6 and 7 is illustrated as a single line in FIG. 1, it is actually constituted by a plurality of lines in some cases. Also, although illustration is omitted in FIG. 1, a plurality of external connection pads are placed in the semiconductor integrated circuit device 1.

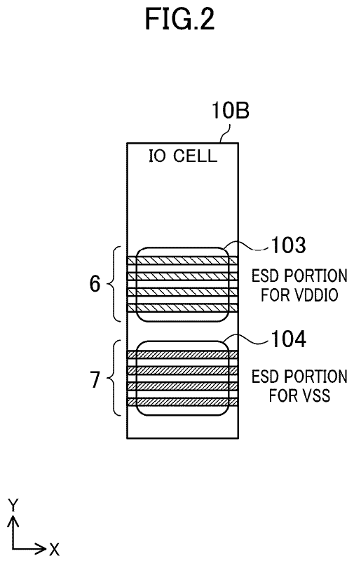

FIG. 2 is a simplified configuration diagram of the IO cell 10B. In FIG. 2, the power lines 6 and 7 are each assumed to have four lines. As shown in FIG. 2, the power lines 6 and 7 extending in the X direction are placed in the IO cell 10B. In this IO cell 10B, an ESD portion 103 for VDDIO is provided under the power lines 6, and an ESD portion 104 for VSS is provided under the power lines 7. The ESD portion 103 for VDDIO and the ESD portion 104 for VSS are provided at positions closer to the chip outer edge in the IO cell 10B.

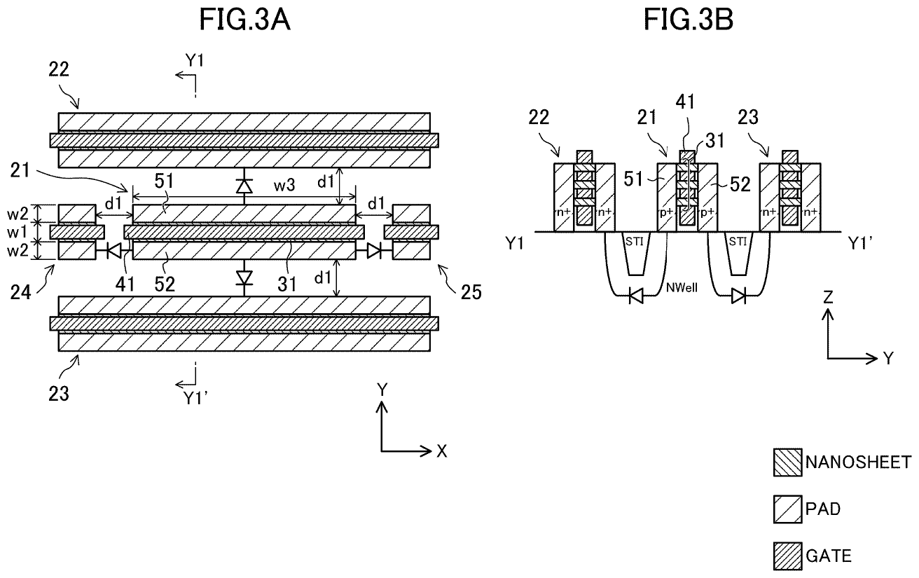

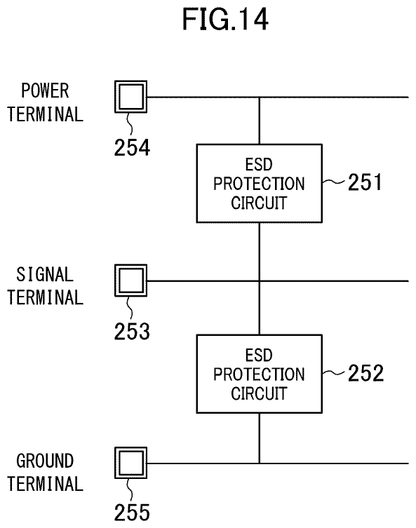

FIGS. 3A-3B are views showing part of the configuration of the ESD portion 103 for VDDIO in this embodiment, in which FIG. 3A is a plan view showing the planar layout and FIG. 3B is a cross-sectional view taken along line Y1-Y1′ in FIG. 3A. The configuration of FIGS. 3A-3B corresponds to the ESD protection circuit 251 provided between the power terminal 254 and the signal terminal 253 in FIG. 14.

In FIG. 3A, a device structure 21 constituting the anode of a diode is placed in the center. Device structures 22, 23, 24, and 25 constituting the cathode of the diode are respectively placed on the upper, lower, left, and right sides of the device structure 21 in the figure. The device structures 21 to 25 are formed on an N-well. A shallow trench isolation (STI) is formed between the device structure 21 and each of the device structures 22 to 25. Note that the device structures 21 to 25 may be formed on a P-well or a P-substrate.

The device structure 21 includes: a set of three nanosheets 31 arranged in the Z direction; a gate interconnect 41 surrounding the nanosheets 31 in the X direction and the Z direction via gate insulating films; and pads 51 and 52 formed on both sides of the gate interconnect 41 in the Y direction and connected to both ends of the nanosheets 31. The nanosheets 31 overlap the gate interconnect 41 in planar view. The pads 51 and 52 constitute a pad group of the device structure 21. The pads 51 and 52 extend in the X direction, have p-type conductivity, and are connected to a signal terminal through interconnects and contacts although illustration is omitted. The pads 51 and 52 are formed by epitaxial growth from the nanosheets 31, for example.

In the device structure 21, the gate interconnect 41 extends in the X direction, and the nanosheets 31 have an shape elongating in the X direction, and the pads 51 and 52 extend in the X direction. The size of the nanosheets 31 in the Y direction is denoted by w1, the size of the pads 51 and 52 in the Y direction is denoted by w2, and the size of the nanosheets 31 and the pads 51 and 52 in the X direction is denoted by w3.

The device structures 22 to 25 each have a structure similar to that of the device structure 21. That is, each of the device structures 22 to 25 includes: a set of three nanosheets arranged in the Z direction; a gate interconnect surrounding the nanosheets in the X and Z directions via gate insulating films; and pads formed on both sides of the gate interconnect in the Y direction and connected to both ends of the nanosheets. The nanosheets overlap the gate interconnect in planar view. The pads constitute a pad group of each of the device structures 22 to 25. In the device structures 22 to 25, the pads have n-type conductivity, and are connected to a power terminal through interconnects and contacts although illustration is omitted.

Diodes are formed between the p-type pads 51 and 52 of the device structure 21 that is to be an anode and the n-type pads of the device structures 22 to 25 that are each to be a cathode. In FIG. 3A, the distances between the device structure 21 and the device structures 22 to 25 are the same, i.e., d1.

The power supply voltage VDDIO is supplied to the gate interconnect 41 of the device structure 21. This prevents a current from flowing to the nanosheets 31 between the pads 51 and 52. Similarly, the power supply voltage VSS is supplied to the gate interconnects of the device structures 22 to 25, and this prevents a current from flowing to the nanosheets between the pads. However, if it is unnecessary to prevent a current flow to the nanosheets, the gates may be put in a floating state. In this case, since interconnects and contacts for supplying a voltage to the gate are unnecessary, other signal lines and power lines can be laid additionally. With this, the ESD protection capability can be improved.

As described above, it is difficult to form the pads for forming diodes independently from the nanosheets. Therefore, in the portions of the device structure 21 opposed to the device structures 24 and 25 in the X direction, the pads 51 and 52 and the nanosheets 31 are present. Since the nanosheets 31 are not in contact with the substrate, they do not function as a diode as described above. Therefore, only the pads 51 and 52, out of the portions of the device structure 21 opposed to the device structures 24 and 25 in the X direction, function as a diode. On the other hand, in the portions of the device structure 21 opposed to the device structures 22 and 23 in the Y direction, only the pads 51 and 52 are present. Therefore, the entire of the portions of the device structure 21 opposed to the device structures 22 and 23 in the Y direction function as a diode.

Herein, an opposing length of a pad of a device structure constituting a diode is defined as follows. That is, for the pad group of a device structure, in a range of the device structure in the Y direction in which a pad is present, the length of a portion in which a pad of another device structure opposed in the X direction is present is defined as the opposing length in the X direction. Also, in a range of the device structure in the X direction in which a pad is present, the length of a portion in which a pad of another device structure opposed in the Y direction is present is defined as the opposing length in the Y direction. In the layout of FIG. 3A, for the pad group of the device structure 21, i.e., the pads 51 and 52, the opposing length in the X direction is w2×4, and the opposing length in the Y direction is w3×2.

Note that, in the layout of FIG. 3A, for the pad group of the device structure 21, i.e., the pads 51 and 52, pads of the opposed device structures 22 to 25 are present in all ranges in which a pad is present both in the X direction and the Y direction. Therefore, the opposing lengths are substantially the same as the sizes of the pad group. Note however that, if any of the other device structures is displaced, or if any of the other device structures is not present, there is a possibility that a portion in which no opposed pad is present may be included in the range in which a pad is present. In such a case, the opposing length of a device structure will be smaller than the size of the pad group by the length of this portion.

The size of the nanosheets in the gate width direction (the X direction in FIG. 3A) can be easily increased. Therefore, the capability of the diode can be enhanced by increasing the size of the nanosheets 31 in the gate width direction, thereby, in the device structure 21, sufficiently increasing the size in the X direction of the pad group opposed in the Y direction, compared with the size in the Y direction of the pad group opposed in the X direction.

Specifically, for the pad group of the device structure 21, by establishing

$$w 3 > w 2 \times 2$$

so that the opposing length in the Y direction be greater than the opposing length in the X direction, a diode large in capability using a nanosheet device can be configured. With this, a small-area ESD protection circuit can be formed.

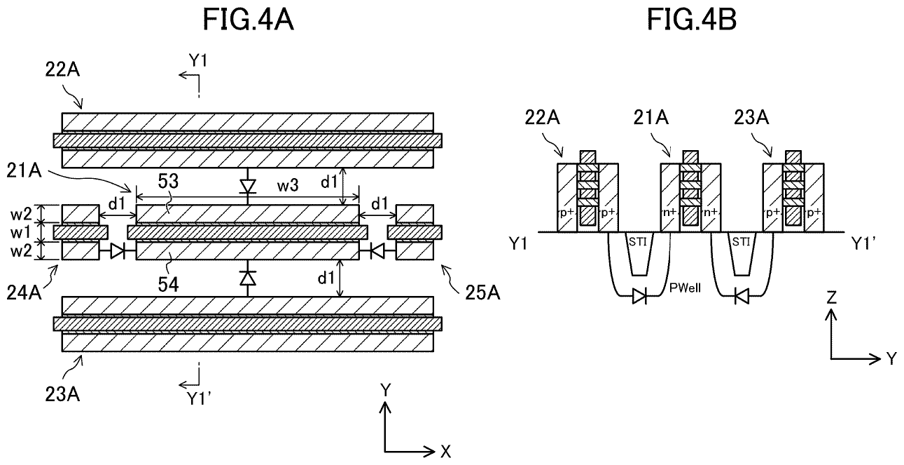

FIGS. 4A-4B are views showing part of the configuration of the ESD portion 104 for VSS in this embodiment, in which FIG. 4A is a plan view showing the planar layout and FIG. 4B is a cross-sectional view taken along line Y1-Y1′ in FIG. 4A. The configuration of FIGS. 4A-4B corresponds to the ESD protection circuit 252 provided between the signal terminal 253 and the ground terminal 255 in FIG. 14.

The configuration of FIGS. 4A-4B is similar to that of FIGS. 3A-3B, except that, in the configuration of FIGS. 4A-4B, the anode and the cathode are opposite, and the conductivity types of the pads are opposite, to those in the configuration of FIGS. 3A-3B.

That is, in FIG. 4A, a device structure 21A constituting the cathode of a diode is placed in the center. Device structures 22A, 23A, 24A, and 25A constituting the anode of the diode are respectively placed on the upper, lower, left, and right sides of the device structure 21A in the figure. The device structures 21A to 25A are formed on a P-well (or a P-substrate). Note that the device structures 21A to 25A may be formed on an N-well.

Pads 53 and 54 of the device structure 21A have n-type conductivity, and are connected to a signal terminal through interconnects and contacts. Pads of the device structures 22A to 25A are connected to a ground terminal through interconnects and contacts.

As in the configuration of FIGS. 3A-3B, for the pad group of the device structure 21A, i.e., the pads 53 and 54, by establishing

$$w 3 > w 2 \times 2$$

so that the opposing length in the Y direction be greater than the opposing length in the X direction, a diode large in capability using a nanosheet device can be configured. With this, a small-area ESD protection circuit can be formed.

Note that, the device structures 22 and 23 in FIGS. 3A-3B and the device structures 22A and 23A in FIGS. 4A-4B each may have a configuration including two or more gate interconnects arranged in the Y direction.

### <Alterations>

The following alterations are based on the configuration of FIGS. 3A-3B. Note however that alterations can also be implemented based on the configuration of FIGS. 4A-4B.

### (Alteration 1)

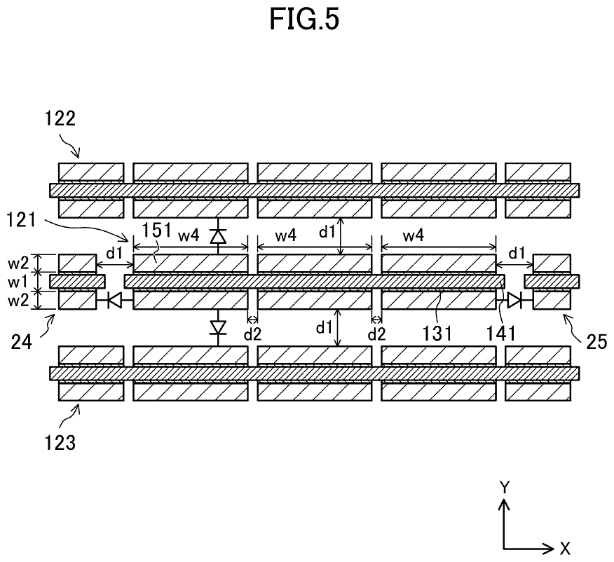

FIG. 5 is a view showing a planar layout of Alteration 1. In FIG. 5, a device structure 121 constituting the anode of a diode is placed in the center. In the device structure 121, nanosheets and pads are each split into three in the X direction. That is, the pad group of the device structure 121 includes a plurality of pads 151 arranged in line in the X direction. The size of each pad 151 in the X direction is w4, and the gap between the adjacent pads 151 is d2. Note that, although a gate interconnect 141 is not split in FIG. 5, the gate interconnect 141 may also be split like nanosheets 131 and the pads 151.

In some cases, the maximum value of the width (size in the channel width direction; size in the X direction in the figure) of nanosheets is specified due to the manufacturing constraints. A plurality of sheet-like semiconductor layers constituting a set of nanosheets are formed by removing, out of two kinds of semiconductor layers (e.g., Si and SiGe) stacked one upon another, one kind of semiconductor layers (e.g., SiGe), for example. At this time, if the width of the nanosheets is large, it will be difficult to remove one kind of semiconductor layers. In consideration of this, in the layout of FIG. 5, the size w4 is made smaller than the maximum value of the width of the nanosheets.

Device structures 122 and 123 constituting the cathode of the diode are respectively placed on the upper and lower sides of the device structure 121. In the device structures 122 and 123, also, as in the device structure 121, the nanosheets and the pads are split in the X direction. In FIG. 5, the split positions of the pads in the device structure 121 agree with the split positions of the pads in the device structures 122 and 123. With this agreement of pad split positions, the opposing length in the Y direction related to the pad group of the device structure 121 increases, whereby the capability of the diode becomes large. Note however that, in device structures opposed to each other in the Y direction, the split positions of pads are not necessarily required to agree with each other.

In the configuration of FIG. 5, for the pad group of the device structure 121, by establishing

$$w 4 \times 3 > w 2 \times 2$$

so that the opposing length in the Y direction be greater than the opposing length in the X direction, a diode large in capability using a nanosheet device can be configured. With this, a small-area ESD protection circuit can be formed.

Note that the number of split parts of the pad of the device structure 121 in the X direction is not limited to three. Also, the split pads 151 are not necessarily required to be uniform in size in the X direction. Assuming that a pad of the device structure 121 is split into n parts (n is an integer equal to or more than 1) in the X direction and the width of each part is wx(i) (i is an integer from 1 to n), a diode large in capability can be configured by satisfying the relationship:

$${\sum }_{i = 1}^{n} wx ( i ) > 2 \cdot w 2 \qquad ( 1 )$$

With this, a small-area ESD protection circuit can be formed.

Note that, as in the embodiment described above, the device structures 122 and 123 each may have a configuration including two or more gate interconnects arranged in the Y direction.

### (Alteration 2)

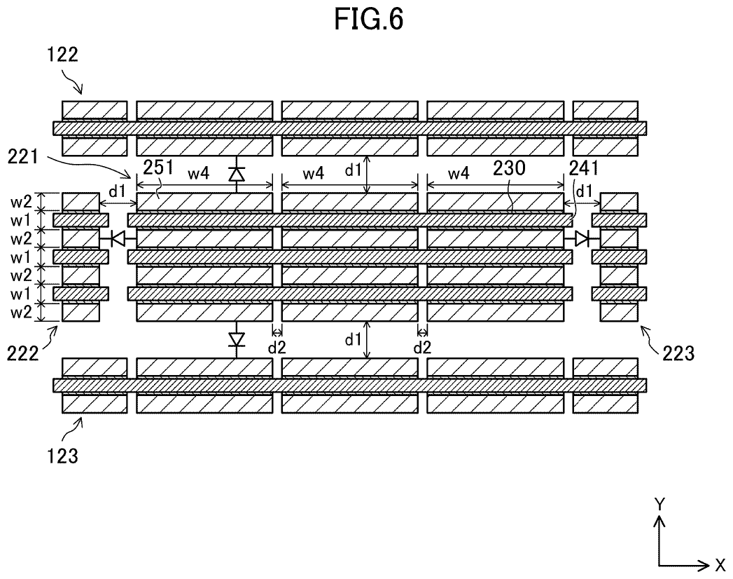

FIG. 6 is a view showing a planar layout of Alteration 2. In FIG. 6, a device structure 221 constituting the anode of a diode is placed in the center. As shown in FIG. 6, the device structure 221 has a configuration of including three gate interconnects 241 extending in the X direction arranged in the Y direction. Also, in the device structure 221, as in the device structure 121 shown in FIG. 5, nanosheets and pads are each split into three in the X direction. The size of each pad 251 is w4 in the X direction and w2 in the Y direction. Note that, although the gate interconnects 241 are not split in FIG. 6, they may also be split like nanosheets 230 and the pads 251.

Device structures 222 and 223 constituting the cathode of the diode are respectively placed on the left and right sides of the device structure 221. The device structures 222 and 223, like the device structure 221, have a configuration of including three gate interconnects arranged in the Y direction. This results in that four pads of the device structure 221 are opposed to four pads of the device structure 222 and to four pads of the device structure 223 in the X direction.

The device structure 221 constituting the anode is connected to a signal terminal. Since the device structure 221 having three gate interconnects 241 arranged in the Y direction is large in size in the Y direction, a thick interconnect can be provided above the device structure 221. By connecting the device structure 221 to the signal terminal via the thick interconnect, the resistance value from the signal terminal to the anode can be reduced, whereby the capability of the ESD protection circuit can be improved.

In the configuration of FIG. 6, for the pad group of the device structure 221, by establishing

$$w 4 \times 3 > w 2 \times 4$$

so that the opposing length in the Y direction be greater than the opposing length in the X direction, a diode large in capability using a nanosheet device can be configured. With this, a small-area ESD protection circuit can be formed.

Note that the number of gate interconnects 241 arranged in the Y direction in the device structure 221 is not limited to three. Also, the number of pads of the device structure 221 opposed to pads of each of the device structures 222 and 223 in the X direction is not limited to four. Also, the width (size in the Y direction) of the opposed pads is not necessarily required to be uniform. Assuming that the number of pads opposed in the X direction is m (m is an integer equal to or more than 1) and the width of each pad is wy(j) (j is an integer from 1 to m), a diode large in capability can be configured by satisfying the relationship:

$${\sum }_{i = 1}^{n} wx ( i ) > {\sum }_{j = 1}^{m} wy ( j ) \qquad ( 2 )$$

With this, a small-area ESD protection circuit can be formed.

The above-described feature will be presented focusing on the pad size of the pad group of a device structure. In a device structure constituting the anode, assume that the number of pads in the X direction is n (n is an integer equal to or more than 1) and the size of each pad in the X direction is wx(i) (i is an integer from 1 to n). Assume also that the number of pads in the Y direction is m (m is an integer equal to or more than 1) and the size of each pad in the Y direction is wy(j) (j is an integer from 1 to m). For this device structure, assume that device structures constituting the cathode are placed so that their pads are opposed to the pads of the above device structure in the X direction and in the Y direction. In this case, by satisfying the same relationship,

$${\sum }_{i = 1}^{n} wx ( i ) > {\sum }_{j = 1}^{m} wy ( j ) \qquad ( 2 )$$

a diode large in capability can be configured.

### (Alteration 3)

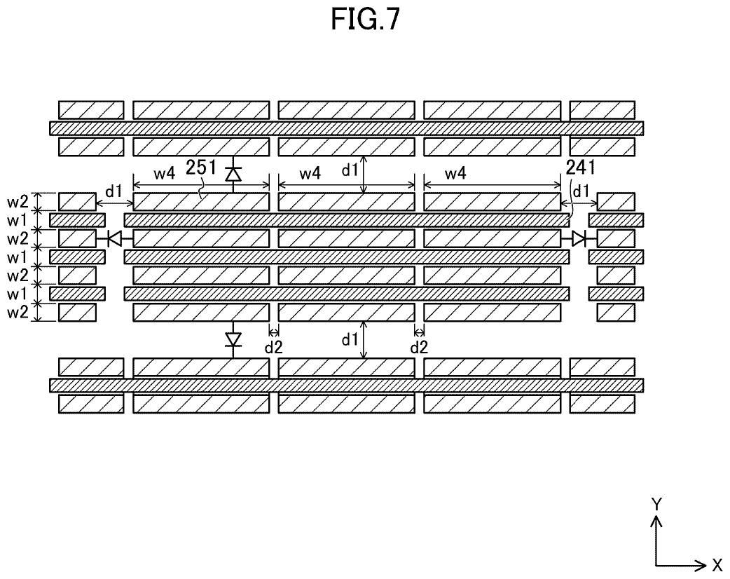

FIG. 7 is a view showing a planar layout of Alteration 3. The configuration of FIG. 7 corresponds to a configuration obtained by removing the nanosheets 230 from the configuration of FIG. 6. In the configuration of FIG. 7, at the occurrence of an ESD event, an ESD current will never flow to nanosheets between pads. Therefore, since it is unnecessary to fix the gate potential, no lines nor contacts for supplying a voltage to the gate interconnects 241 are necessary, whereby other signal lines and power lines can be laid additionally. With this, the ESD protection capability can be improved.

The configuration of FIG. 7 can be implemented in a manufacturing process as follows, for example. After pads are formed by epitaxial growth from nanosheets, the gate interconnects are removed once, and then the nanosheets are removed while the pad portions are masked. Thereafter, gate interconnects are formed again in the places where the former gate interconnects were present.

Note that the gate interconnects may be omitted in the configuration of FIG. 7. However, in order to avoid uneven density of a pattern in the layout of the entire semiconductor chip, it is preferable to place the gate interconnects.

### (Alteration 4)

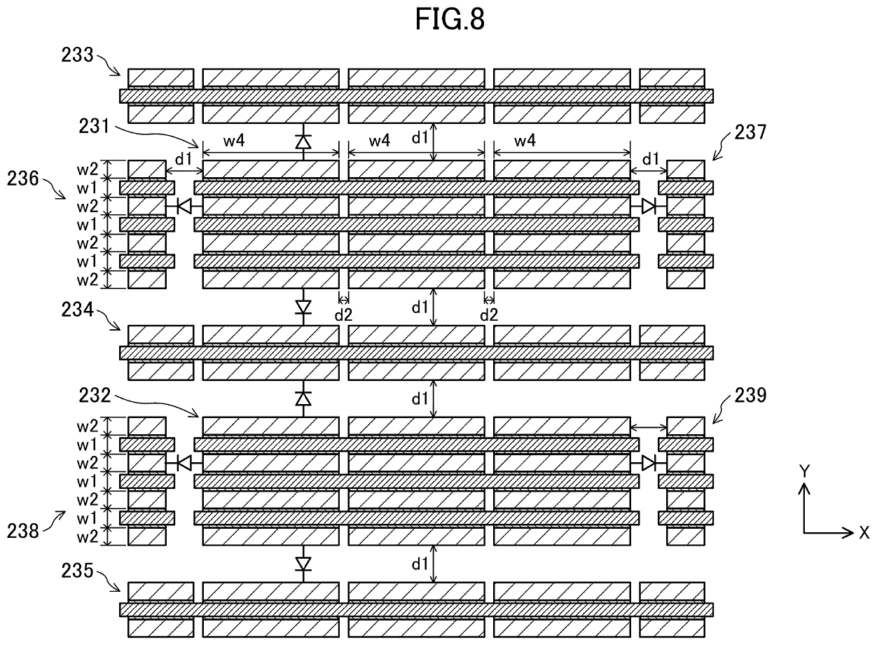

FIG. 8 is a view showing a planar layout of Alteration 4. The configuration of FIG. 8 corresponds to a configuration obtained by placing the configuration of FIG. 6 repeatedly in the Y direction. In the configuration of FIG. 8, two device structures 231 and 232 constituting the anode of a diode are arranged in the Y direction. The device structures 231 and 232 have the same configuration as the device structure 221 shown in FIG. 6.

Device structures 233, 234, and 235 constituting the cathode of the diode are respectively placed on the upper side of the device structure 231, between the device structures 231 and 232, and on the lower side of the device structure 232, in the figure. The device structures 233, 234, and 235 have the same configuration as the device structures 122 and 123 shown in FIG. 6. Device structures 236 and 237 constituting the cathode of the diode are respectively placed on the left and right sides of the device structure 231 in the figure. Device structures 238 and 239 constituting the cathode of the diode are respectively placed on the left and right sides of the device structure 232 in the figure. The device structures 236, 237, 238, and 239 have the same configuration as the device structures 222 and 223 shown in FIG. 6.

In the configuration of FIG. 8, the device structure 234 functions as the cathode for the device structure 231 and also as the cathode for the device structure 232. That is, the device structure 234 is shared as the cathode by the device structures 231 and 232, whereby reduction in area is achieved.

Note that the configuration of FIG. 6 may be placed repeatedly two or more times. Also, the configuration of FIG. 6 may be placed repeatedly in the X direction. In this case, also, a device structure located between device structures constituting the anode may be made to function as a common cathode. In place of the configuration of FIG. 6, any other configuration described above may be placed repeatedly.

The device structures 233, 234, and 235 in FIG. 8 each may have a configuration including two or more gate interconnects arranged in the Y direction.

### (Alteration 5)

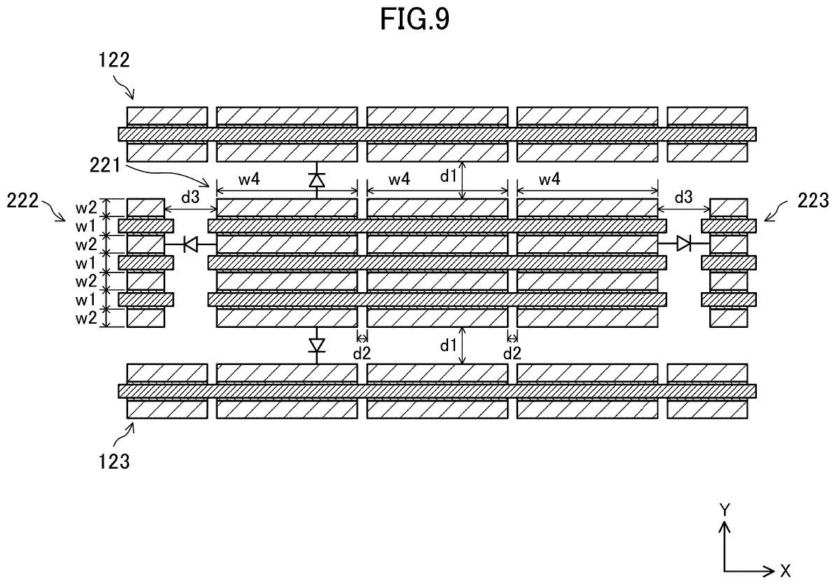

FIG. 9 is a view showing a planar layout of Alteration 5. The configuration of FIG. 9 corresponds to a configuration obtained by making the anode-cathode distance in the X direction greater than the anode-cathode distance in the Y direction in the configuration of FIG. 6. That is, the distance d3 between the device structure 221 constituting the anode and each of the device structures 222 and 223 constituting the cathode located on the left and right sides of the device structure 221 in the figure is greater than the distance d1 between the device structure 221 and each of the device structures 122 and 123 constituting the cathode located on the upper and lower sides of the device structure 221 (d3>d1).

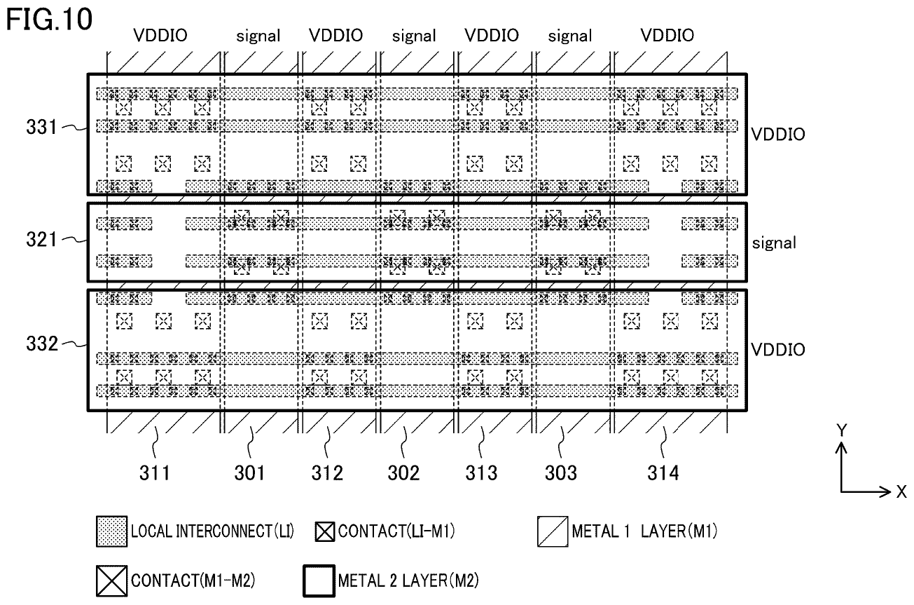

FIG. 10 is a view showing a configuration example of interconnects placed above the configuration of FIG. 9. In FIG. 10, local interconnects are placed on the pads shown in FIG. 9 and are in contact with the underlying pads. In a first metal layer (M1), metal interconnects extending in the Y direction are placed. Metal interconnects 301, 302, and 303 are signal lines and connected to the local interconnects in contact with the pads of the device structure 221. Metal interconnects 311, 312, 313, and 314 are power lines and connected to the local interconnects in contact with the pads of the device structures 122, 123, 222, and 223. In a second metal layer (M2), metal interconnects extending in the X direction are placed. A metal interconnect 321 is a signal line and connected to the metal interconnects 301, 302, and 303 via contacts. Metal interconnects 331 and 332 are power lines and connected to the metal interconnects 311, 312, 313, and 314 via contacts. The metal interconnects 331 and 332 correspond to the power line 6 shown in FIGS. 1 and 2.

As is found from FIG. 10, since the device structures 122 and 123 opposed to the device structure 221 in the Y direction are sufficiently large in size in the X direction, a number of contacts can be placed for connecting the local interconnects in contact with the pads and the metal interconnects. Therefore, in the device structures 122 and 123, the resistance value related to the connection with power lines can be kept low. On the other hand, since the device structures 222 and 223 opposed to the device structure 221 in the X direction are small in size in the X direction, it is not possible to place a number of contacts for connecting the local interconnects in contact with the pads and the metal interconnects. Therefore, in the device structures 222 and 223, it is difficult to keep low the resistance value related to the connection with power lines.

In the case described above, if a large ESD current flows between the anode and the cathode, a large current may be concentrated in the device structures 222 and 223 opposed in the X direction, raising a possibility of destroying contacts and interconnects located above.

In consideration of the above, in this alteration, the anode-cathode distance d3 in the X direction is made greater than the anode-cathode distance d1 in the Y direction, thereby increasing the resistance value in the X direction. With this, since the ESD current flowing in the X direction can be reduced, the above-described problem can be avoided.

### (Alteration 6)

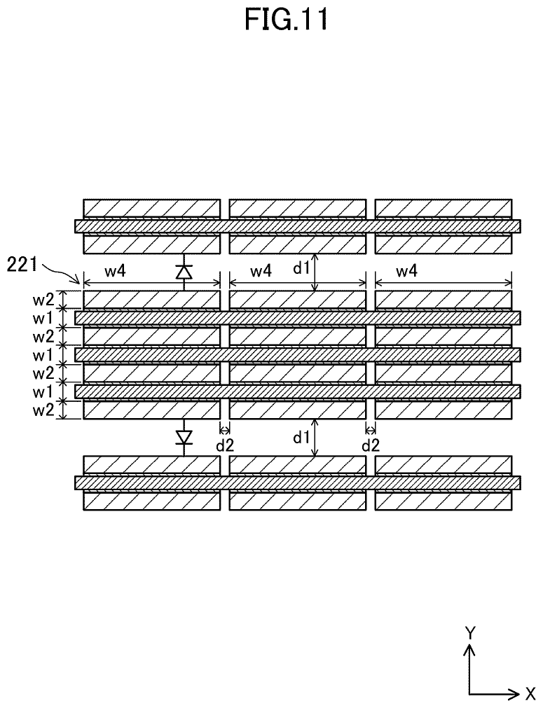

FIG. 11 is a view showing a planar layout of Alteration 6. The configuration of FIG. 11 corresponds to a configuration obtained by deleting the portions, including the device structures 222 and 223, located on the left and right sides of the device structure 221 in the figure from the configuration of FIG. 6.

In the configuration of FIG. 11, in which pads of the device structure 221 are opposed to pads of other device structures in the Y direction, since the opposing length is sufficiently large, the diode capability is large. The area of the configuration of FIG. 11 is smaller than that of the configuration of FIG. 6. Also, the problem described in Alteration 5, of destroying contacts and interconnects located above due to a large current concentrated in the device structures 222 and 223 opposed in the X direction, does not occur.

Note that, in this alteration, for the pad group of the device structure 221, since there are no pads opposed in the X direction, this configuration corresponds to an expression in which the right side of the expression

$${\sum }_{i = 1}^{n} wx ( i ) > {\sum }_{j = 1}^{m} wy ( j ) \qquad ( 2 )$$

shown in Alteration 2 is replaced with 0.

### (Alteration 7)

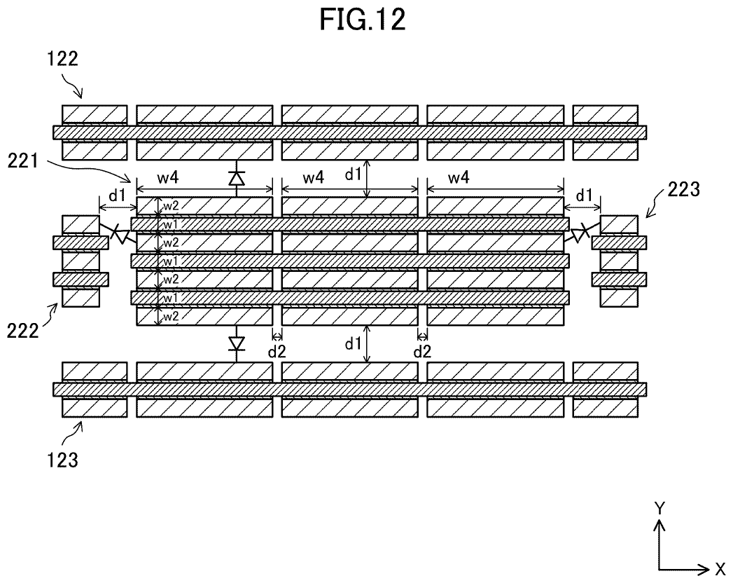

FIG. 12 is a view showing a planar layout of Alteration 7. The configuration of FIG. 12 corresponds to a configuration obtained by displacing the positions of the device structures 222 and 223 in the Y direction in the configuration of FIG. 6. In the configuration of FIG. 12, the distance between the pads of the device structure 221 constituting the anode and the pads of each of the device structures 222 and 223 constituting the cathode is greater than d1. With this, since the anode-cathode resistance value in the X direction increases as in Alteration 5, an effect similar to that in Alteration 5 can be obtained.

Note that this alteration may be combined with Alteration 5. That is, the distance between the device structure 221 constituting the anode and each of the device structures 222 and 223 constituting the cathode may be made large, and also the positions of the device structures 222 and 223 may be displaced in the Y direction.

1. A semiconductor integrated circuit device including a nanosheet field effect transistor (FET), comprising
an electrostatic discharge (ESD) protection circuit,
wherein
the nanosheet FET includes a nanosheet and pads connected to both ends of the nanosheet,
the ESD protection circuit includes
a first device structure constituting one of an anode and a cathode of a diode,
a second device structure constituting the other of the anode and the cathode of the diode, opposed to the first device structure in a first direction, and
a third device structure constituting the other of the anode and the cathode of the diode, opposed to the first device structure in a second direction perpendicular to the first direction,
the first device structure includes
one, or two or more first gate interconnects arranged in the second direction, extending in the first direction, and
a first pad group constituted by pads of a first conductivity type extending in the first direction, placed on both sides of the first gate interconnect in the second direction,
the second device structure includes
one, or two or more second gate interconnects arranged in the second direction, extending in the first direction, and
a second pad group constituted by pads of a second conductivity type extending in the first direction, placed on both sides of the second gate interconnect in the second direction,
the third device structure includes
one, or two or more third gate interconnects arranged in the second direction, extending in the first direction, and
a third pad group constituted by pads of the second conductivity type extending in the first direction, placed on both sides of the third gate interconnect in the second direction, and
a length of a range in the first direction in which the first pad group and the third pad group are opposed to each other in the second direction is greater than a length of a range in the second direction in which the first pad group and the second pad group are opposed to each other in the first direction.

2. The semiconductor integrated circuit device of claim 1, wherein
the first device structure includes
a first nanosheet having an overlap with the first gate interconnect in planar view,
the second device structure includes
a second nanosheet having an overlap with the second gate interconnect in planar view, and
the third device structure includes
a third nanosheet having an overlap with the third gate interconnect in planar view.

3. The semiconductor integrated circuit device of claim 1, wherein
the first pad group includes a plurality of pads arranged in line in the first direction.

4. The semiconductor integrated circuit device of claim 1, wherein
the first gate interconnect is constituted by a plurality of interconnects arranged in line in the first direction.

5. The semiconductor integrated circuit device of claim 1, wherein
the first gate interconnect is in a floating state.

6. A semiconductor integrated circuit device including a nanosheet field effect transistor (FET), comprising
an electrostatic discharge (ESD) protection circuit,
wherein
the nanosheet FET includes a nanosheet and pads connected to both ends of the nanosheet,
the ESD protection circuit includes
a first device structure constituting one of an anode and a cathode of a diode,
a second device structure constituting the other of the anode and the cathode of the diode, opposed to the first device structure in a first direction, and
a third device structure constituting the other of the anode and the cathode of the diode, opposed to the first device structure in a second direction perpendicular to the first direction,
the first device structure includes
a first pad group constituted by pads of a first conductivity type extending in the first direction,
the second device structure includes
a second pad group constituted by pads of a second conductivity type extending in the first direction,
the third device structure includes
a third pad group constituted by pads of the second conductivity type extending in the first direction, and
a length of a range in the first direction in which the first pad group and the third pad group are opposed to each other in the second direction is greater than a length of a range in the second direction in which the first pad group and the second pad group are opposed to each other in the first direction.

7. The semiconductor integrated circuit device of claim 6, wherein
the first pad group includes a plurality of pads arranged in line in the first direction.
